(19) United States
(12) Patent Application Publication
(10) Pub. No.: US 2010/0247933 A1
(43) Pub. Date: Sep. 30, 2010

(54) COATING, SUBSTRATE PROVIDED WITH A COATING AND METHOD FOR THE APPLICATION OF A CORROSION-RESISTANT COATING

(75) Inventors: Ian John Bennet, GL Rijswijk (NL); Willem Gerrit Sloof, DJ Delft (NL)

Correspondence Address: SUGHRUE MION, PLLC, 2100 PENNSYLVANIA AVENUE, N.W., SUITE 800, WASHINGTON, DC, 20037, US

(73) Assignee: NETHERLANDS INSTITUTE FOR METALS RESEARCH, CD Delft (NL)

(21) Appl. No.: 11/909,585

(22) PCT Filed: Mar. 24, 2006
(86) PCT No.: PCT/NL06/50063

§ 371 Date: Jun. 16, 2010

(30) Foreign Application Priority Data
Mar. 24, 2005 (NL) 1028629

(51) Int. Cl. B32B 15/04; C23C 14/34; C23C 4/08

(52) U.S. Cl. 428/457; 204/192.15; 427/455; 420/591

(57) ABSTRACT

Substrate such as a turbine blade provided with a coating, which consists of a material that forms a sealing oxide skin on heating. This material is a ferrous metal aluminium alloy or a ferrous metal chromium alloy, wherein the oxide skin comprises aluminium oxide or chromium oxide. In order to optimise the adhesion between the skin and the coating, it is proposed that a metal from the platinum group such as platinum or palladium be added in an amount of 0.1-0.5% (m/m). It has been found that better adhesion is obtained with this method and the detrimental effects of sodium, potassium or calcium are counteracted.

The present invention relates to a coating comprising a ferrous metal aluminium or ferrous metal chromium alloy, said alloy forming an aluminium oxide or chromium oxide skin, respectively, on contact with oxygen, said skin being impermeable to oxygen.

A coating of this type is used notably with materials that are exposed to high temperatures. Examples of this are turbine blades in combustion engines, applications in electronics such as photovoltaic devices, sensors and the like.

If, for example, a nickel aluminium alloy is used, aluminium oxide will be formed on the surface at relatively high temperature that in principle forms a skin impermeable to oxygen, as a result of which protection for the underlying metal is obtained. It is important, however, that such an oxide skin formed at elevated temperatures has sufficient adhesion to the underlying metal.

In the prior art, a further protective layer is applied to the coating. In U.S. Pat. No. 4,123,592, for example, a thin platinum layer is applied by sputtering after the application of the coating. As a result of the application of platinum to the surface the diffusion rate of aluminium us increased, as a result of which rapid closure of the surface takes place in the event of damage to the surface.

A coating is also disclosed in U.S. Pat. No. 6,183,888 to which a further protective layer containing platinum is applied.

U.S. Pat. No. 6,458,473 B1 describes a coating built up of several layers.

US 2003/0041928 A1 describes the application of a coating and the subsequent polishing of the surface before the application of the protective oxide. Platinum is applied in a separate step.

U.S. Pat. No. 4,123,594 describes a coating consisting of different layers and in which 1-30% (m/m) platinum or palladium is incorporated.

U.S. Pat. No. 4,346,137 describes a coating built up of different layers each with a different coefficient of expansion.

A process is disclosed in U.S. Pat. No. 3,918,139 A in which 5-10% (m/m) platinum is deposited in a coating in a separate step. Adhesion between the protective oxide layer and the bond coating is achieved with rare earths.

The aim of the present invention is to provide a coating, which can be used at high temperatures, can be applied simply and inexpensively and where it is not necessary to apply a further protective layer thereon. That is to say the objective is to provide a coating, where on heating a sealing oxide layer is formed that has good adhesion to the original coating.

This aim is realised with the coating described above with the characteristic features of claim 1. The metal from the platinum group, such as platinum, palladium or rhodium is at least near the free interface of the coating, i.e. the part of the coating facing away from the underlying substrate integrated into the alloy, i.e. forms part of the alloy. In contrast to the prior art, a further layer applied thereon is not provided. The alloy as applied has in principle a constant composition during application, i.e. the same percentage of a metal from the platinum group is always applied. In a manner known per se, a chromium and/or aluminium oxide layer will subsequently be formed. Only a relatively small percentage of the metal from the platinum group is necessary. A value of 0.1% (m/m) is mentioned as a lower limit. A value of about 0.5% (m/m) is mentioned as maximum.

Surprisingly it has been found that when using such an alloy significantly improved adhesion occurs between the oxide formed and the original coating.

Although not essential for the invention it is assumed that reduced adhesion of the oxide layer to the coating, as has been observed, is caused not only by the presence of sulphur and carbon but also by the presence of sodium, potassium or calcium. These materials can be present as impurities during formation of the alloys in amounts of 1 ppm−0.1% (m/m). As an example, the lining material of furnaces in which the ferrous metal chromium alloy or ferrous metal aluminium alloy is melted may be mentioned. It is assumed that by the addition of platinum or palladium, sodium, potassium or calcium is immobilized in the alloy. As a result, sodium, potassium or calcium cannot diffuse to the interface, where they have an adverse effect on the adhesion between the oxide skin formed/to be formed and the alloy. It has been observed that the adhesion between the alloy and the oxide layer can be decreased by a factor of more than 2 because of the presence of sodium, potassium or calcium.

“Ferrous metal” is understood to relate here in particular to iron alloys, nickel alloys and cobalt alloys. More particularly, at high temperatures, nickel alloys such as nickel aluminium alloys and more particularly B-nickel aluminium alloys are used. In turbine motors, where the temperature can reach more than 1600° C. and the surface temperature of the blades is about 1200° C., the β-NiAl alloys described above are employed. At such high temperatures, α-Al₂O₃ is formed as a sealing oxide layer. In the prior art, delamination of such an oxide layer has been observed.

According to the present invention, by adding the alloy from the platinum group described above, at least near the interface between the alloy and the oxide skin it has been found that the adhesion of such an oxide skin is significantly improved, while it is still guaranteed that such an oxide skin is impermeable.

It will be understood that the same mechanism is also observed in other applications. At somewhat lower temperatures, i.e. up to 900° C., preference is given to the combination of nickel or iron with chromium, Cr₂O₃ being formed on heating. At higher temperatures, i.e. above 900° C., preference is given to aluminium as an addition to iron, nickel or cobalt.

The invention also relates to a substrate comprising a backing material such as a turbine blade and the coating described above applied thereon. Any other backing material can be used instead of a turbine blade.

The invention also relates to a method for the application of a corrosion-resistant protective layer to a substrate, comprising deposition of a coating on said substrate, which coating comprises a ferrous metal aluminium alloy, a ferrous metal chromium alloy, which alloy forms an aluminium oxide or chromium oxide skin, respectively, on contact with oxygen, which skin is impermeable to oxygen, characterised in that only a single coating is deposited on said substrate, wherein the alloy of said coating contains 0.1-0.5% (m/m) of a metal from the platinum group and sodium, potassium or calcium. That is to say the addition of a metal from the platinum group described above takes place during the application of the coating. However, this addition is incorporated in the coating and is not applied thereon. Only a single coating, which provides the protective oxide skin, is applied to the substrate. A significant reduction in costs can be obtained by the application in one step in contrast to the state of the art.

The application of such a coating can be achieved with any method known in the state of the art. According to an advantageous embodiment, PVD or plasma spraying is employed.

With the techniques mentioned here, wherein the protective coating is grown on, it is possible, if the metal from the platinum alloy is added at that moment, to vary the concentration of the metal from the platinum group during the growth, i.e. in particular to add the desired quantity of platinum or palladium when the boundary front of the layer is being grown. After all, this part will be converted first to aluminium or chromium oxide. However, in view of the small amount of material from the platinum group, it is not important for cost reasons to add the metal from the platinum group already during the first deposit of the layer.

The layer thickness of such a coating is preferably between 50 and 200 μm.

It is of course possible to add materials known in the state of the art to the coating or to apply further layers thereon.

After reading the above, variants will be immediately apparent to those skilled in the art that are obvious and fall within the scope of the appended claims.

1-9. (canceled)

10. Coating comprising a ferrous metal aluminium or ferrous metal chromium alloy, said alloy forming an aluminium oxide or chromium oxide skin, respectively, on contact with oxygen, said skin being impermeable to oxygen said coating comprising an alloy with a homogeneous composition containing sodium, potassium or calcium as well as 0.1-0.5% (m/m) of a metal from the platinum group and an oxide layer of said alloy adjacent thereto.

11. Coating according to claim 10, wherein said alloy contains 1 ppm−0.1% (m/m) sodium, potassium or calcium.

12. Coating according to claim 10, wherein said alloy comprises a NiAl alloy.

13. Substrate comprising a support and a protective layer applied thereon, wherein said protective layer comprises solely a coating comprising a ferrous metal aluminium or ferrous metal chromium alloy, said alloy forming an aluminium oxide or chromium oxide skin, respectively, on contact with oxygen, said skin being impermeable to oxygen said coating comprising an alloy with a homogeneous composition containing sodium, potassium or calcium as well as 0.1-0.5% (m/m) of a metal from the platinum group and an oxide layer of said alloy adjacent thereto.

14. Substrate according to claim 13, comprising a turbine blade.

15. Method for the application of a corrosion-resistant protective layer to a substrate, comprising deposition of a coating on said substrate, which coating comprises a ferrous metal aluminium alloy, a ferrous metal chromium alloy, which alloy forms an aluminium oxide or chromium oxide skin, respectively, on contact with oxygen, which skin is impermeable to oxygen, wherein only a single coating is deposited on said substrate, wherein the alloy of said coating contains 0.1-0.5% (m/m) of a metal from the platinum group and sodium, potassium or calcium.

16. Method according to claim 15 comprising the addition of the metal from the platinum group during the deposition process.

17. Method according to claim 15 comprising PVD.

18. Method according to one of claims 16 comprising plasma spraying.
